(19) United States
(12) Patent Application Publication
(10) Pub. No.: US 2007/0008689 A1
(43) Pub. Date: Jan. 11, 2007

(54) LCD driver IC and method of arranging pads in the driver integrated circuit

(76) Inventor: Hyun-Sang Park, Seongnam-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/354,902

(22) Filed: Feb. 16, 2006

(30) Foreign Application Priority Data
Jul. 7, 2005 (KR) 10-2005-0060991

(51) Int. Cl. H05K 5/00

(52) U.S. Cl. 361/683

(57) ABSTRACT

Provided is a driver integrated circuit (IC) adapted for use with a liquid crystal display (LCD) and a method of arranging pads in the driver integrated IC. The driver IC, which outputs driving signals to the LCD, includes a signal input unit, an output channel unit and a signal output unit. The signal input unit has first pads through which a plurality of voltages and first signals are input. The output channel unit includes a plurality of output channel pads that are arranged in a staggered form with respect to a bisector line of a short side of the driver IC. The output channel unit processes the first signals and outputs the processed results as driving signals through output channel pads. The signal output unit includes second pads through which a plurality of voltages are input and second signals are output according to the driving signals.

### BACKGROUND OF THE INVENTION

1. Field of the Invention

Embodiments of the invention relate to driver integrated circuits (ICs) adapted for use with liquid crystal displays (LCDs) and to a method of arranging pads in the driver IC. More particularly, embodiments of the invention relate to LCD driver ICs having a pad arrangement in which the pulse shift direction of LCD driving signals is fixed. Embodiments of the invention also relate to a method of arranging the such pads.

This application claims priority to Korean Patent Application No. 10-2005-60991 filed on Jul. 7, 2005, the subject matter of which is hereby incorporated by reference.

2. Description of the Related Art

FIG. (FIG.) 1A illustrates the layout configuration of a conventional chip-on-film (COF) type, thin film transistor (TFT)—liquid crystal display (LCD) panel having a single bank drive. FIG. 1B illustrates the layout configuration of another conventional COF type, TFT-LCD panel having a dual bank drive.

Referring first to FIG. 1A, gate driver integrated circuits (ICs) 10 and source driver ICs 11 are respectively attached to the short side and long side of the TFT-LCD panel having a single bank drive. Each gate driver IC 10 turns the gate of a pixel TFT (not shown) contained within the TFT-LCD panel ON or OFF, and each source driver IC 11 supplies an electrical charge (generally in the form of pulses signals) to the pixel TFT cell in order to store data within the TFT cell.

Referring to FIG. 1B, when the TFT-LCD panel has a relatively large size, a dual bank drive scheme is typically used. Within this dual bank scheme, gate driver ICs 12 and source driver ICs 13 are respectively attached to opposing short side and long sides of the TFT-LCD panel. Each of the gate and source driver ICs 12 and 13 inputs data and pulse signals sequentially to TFTs formed on a substrate. In conventional TFT-LCD panels having dual bank drive, the shift directions for the respective outputs of driver ICs facing each other are opposite one to another.

FIG. 2 illustrates a pad arrangement for the gate driver ICs of a conventional LCD panel having a dual bank drive. Referring to FIG. 2, each gate driver IC includes a plurality of signal input/output (I/O) pads 20, a plurality of signal processing units 21, and a plurality of output channel pads 22. Control signals, such as a power supply voltage, a ground voltage, a clock signal, and a carry signal, which are required to operate the driver IC, are input to or output from the signal I/O pads 20. Although not illustrated, each signal processing unit 21 includes, for example, a shift register, a level shifter, and a buffer, and processes data or signals received via a corresponding signal I/O pad 20 and transmits the processing result to a corresponding output channel pad 22. Each output channel pad 22 generates a driving signal that allows pixel TFTs to be sequentially selected via an output terminal (not shown).

In FIG. 2, the center bold arrow indicates a shift direction (from G1 to Gn relative to the right hand gate driver IC) in which a scan pulse output from each gate driver IC is shifted. In order to correlate the scan pulses output from two opposing gate driver ICs (e.g., define a common shift direction), each gate driver IC requires an input pad UD for selection of a pulse shift direction. Also, each signal processing unit 21 requires a multiplexer, before the shift register, that selects one of outputs Qn−1 and Qn+1 output from upper and lower shift registers according to the selected direction and inputs the selected output Qn−1 or Qn+1 to a current shift register. The current shift register receives the output Qn−1 or Qn+1 according to the selected direction and outputs an output Qn.

Accordingly, the driver IC pads must be arranged such that a shift direction of signals output from the driver IC is fixed without loss of general purpose use.

### SUMMARY OF THE INVENTION

Embodiments of the invention provides a driver integrated circuit (IC) adapted for use with a liquid crystal display (LCD) panel having a dual bank drive in which pads are arranged to fix a shift direction of signals output from the driver IC. Embodiments of the invention are also related to a method of arranging the such pads.

Thus, in one embodiment, the invention provides a driver integrated circuit (IC) adapted to provide driving signals to a liquid crystal display, comprising; a signal input unit comprising first pads adapted to receive a plurality of voltages and first signals, an output channel unit comprising a plurality of output channel pads arranged in a staggered pattern across the driver IC, and adapted to receive and process the first signals, and output results as the driving signals via the plurality of output channel pads, and a signal output unit comprising second pads adapted to receive the plurality of voltages and second signals, and output the driving signals in accordance therewith.

In another embodiment, the invention provides a method of arranging pads in a driver integrated circuit adapted to provide driving signals to a liquid crystal display, the method comprising; arranging a plurality of first pads on one end of a driver integrated circuit (IC), arranging a plurality of output channel pads adapted to output the driving signals in a staggered pattern across the driver IC, and arranging a plurality of second pads on an opposite end of the driver IC, such that the plurality of output channel pads is bracketed between the plurality of first pads and the plurality of second pads.

In yet another embodiment, the invention provides a dual-bank driver integrated circuit (IC) adapted for use on opposite sides of a liquid crystal display (LCD) panel and further adapted to provide first driving signals and second driving signals in a directionally similar sequence, to the LCD panel, the dual-bank driver IC comprising; a plurality of first driver integrated circuits located on a side of the LCD panel and adapted to provide the first driving signals to the LCD panel through first output channel pads arranged in a pattern on each respective first driver integrated circuit, and a plurality of second driver integrated circuits located on an opposite side of the LCD panel and adapted to provide the second driving signals through second output channel pads arranged identically with the first output pads.

### BRIEF DESCRIPTION OF THE DRAWINGS

Several embodiments of the invention will be described with reference to the attached drawings in which:

FIG. 1A illustrates a layout configuration for a conventional chip-on-film (COF), type thin film transistor (TFT)—liquid crystal display (LCD) panel having a single bank drive;

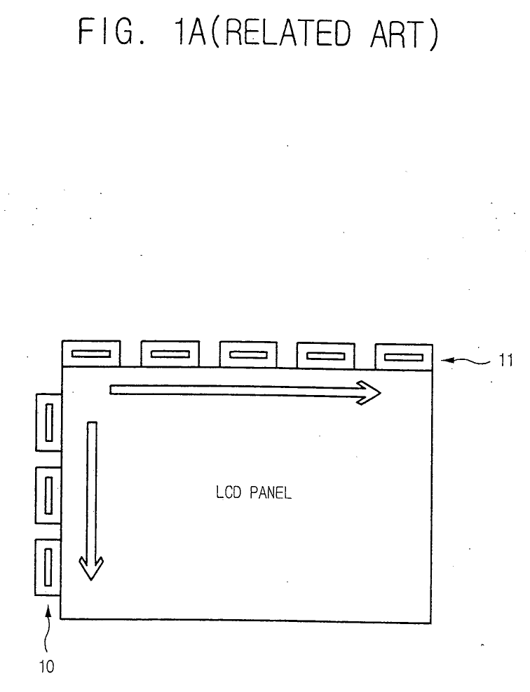

FIG. 1B illustrates a layout configuration for a conventional COF type, TFT-LCD panel having a dual bank drive;

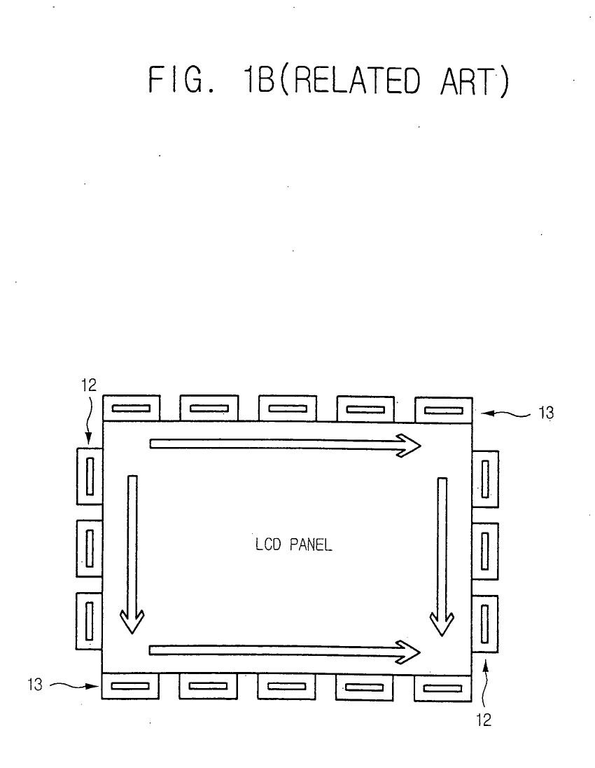

FIG. 2 illustrates an arrangement of pads for a conventional gate driver IC of a LCD panel having a dual bank drive;

FIG. 3 illustrates an arrangement of pads for the gate driver IC of an LCD panel having a dual bank drive according to an embodiment of the invention;

FIG. 4A illustrates an arrangement of pads for a gate driver IC when a total number of output channels is an even number according to an embodiment of the invention;

FIG. 4B illustrates an arrangement of pads for a gate driver IC when a total number of output channels is an odd number according to an embodiment of the invention;

FIGS. 5A and 5B comparatively illustrate arrangements of pads for a conventional driver IC and a driver IC according to an embodiment of the invention, respectively;

FIGS. 6A and 6B comparatively illustrate in some additional detail an arrangements of pads for a conventional driver IC and a driver IC according to an embodiment of the invention, respectively; and

FIGS. 7A and 7B illustrate arrangement examples of signal input/output (I/O) pads for a driver IC according to various embodiments of the invention.

### DESCRIPTION OF EXEMPLARY EMBODIMENTS

Hereinafter, exemplary embodiments of the invention will be described in some additional detail with reference to the accompanying drawings.

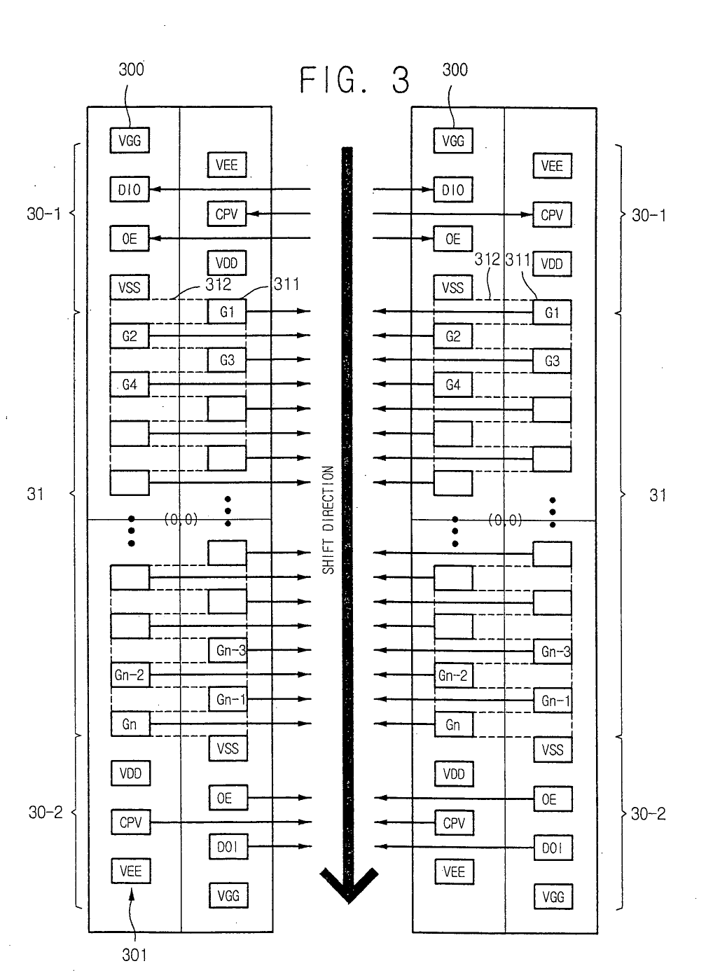

FIG. 3 illustrates an arrangement of pads for a liquid crystal display (LCD) gate driver integrated circuits (ICs) according to an embodiment of the invention. Although the described embodiments are drawn to a gate driver IC example, (for the sake of clarity), it will be appreciated that following teachings may also be applied to a source driver IC.

Referring to FIG. 3, each driver IC comprises a signal input unit 30-1, an output channel unit 31, and a signal output unit 30-2.

The signal input unit 30-1 comprises pads 300 arranged on one end of the driver IC. Pads 300 include, for example, power supply voltage pads (e.g., VDD and VGG), ground voltage pads (e.g., VSS and VEE), an input carry signal pad (DI), an input clock signal pad (CPV), and an output enable signal pad (OE).

The signal output unit 30-2 comprises pads 301 arranged on the other end of driver IC, Pads 301 include, for example, power supply voltage pads (VDD and VGG), ground voltage pads (VSS and VEE), an output carry signal pad (DO), an output clock signal pad (CPV), and an output enable signal pad (OE). As illustrated in FIG. 3, pads 300 of the signal input unit 30-1 and/or pads 301 of the signal output unit 30-2 may be arranged in a staggered layout pattern.

In the illustrated embodiment, the signal input unit 30-1 and signal output unit 30-2 are respectively located at opposite ends of driver IC and bracket the channel output unit 31.

The output channel unit 31 comprises a plurality of output channel pads 311 and a plurality of circuits adapted to signal processing (i.e., signal processors) 312. Although not shown, each signal processor 312 may include for example a shift register and a buffer. As to be described in some additional detail below, respective signal processors 312 do not require a multiplexer to select a shift direction for a scan pulse since the shift direction is fixed.

In the embodiment illustrated in FIG. 3, the output channel unit 31 comprises output channel pads 311 arranged in a staggered pattern across the driver IC. An input and output direction for the carry signal and a shift direction for the scan pulses may be fixed (e.g., from G1 to Gn or from Gn to G1). That is, in the illustrated embodiment, when driver ICs are respectively attached to opposing sides of an LCD panel, the shift direction may be fixed and maintained in a sequence running from G1 to Gn, or the reverse. By way of comparison, conventional driver ICs attached to opposing sides of an LCD panel have opposite running sequences one to another. Thus, in the driver IC according to the present embodiment, a carry signal is received via the input carry signal pad (DI), scan pulses are output in a direction running from G1 to Gn, and the carry signal is output via the output carry signal pad (DO).

When driver ICs are implemented using chip-on-film (COF) technology, a change in the output direction relative to the location of a driver IC may be readily implemented by a change of wiring direction for the metal on film, as illustrated in FIG. 3. When driver ICs are implemented using a chip-on-glass (COG) technology, a similar change in the output direction may be implemented by an arrangement of driver circuits on the panel glass, as illustrated in FIG. 3.

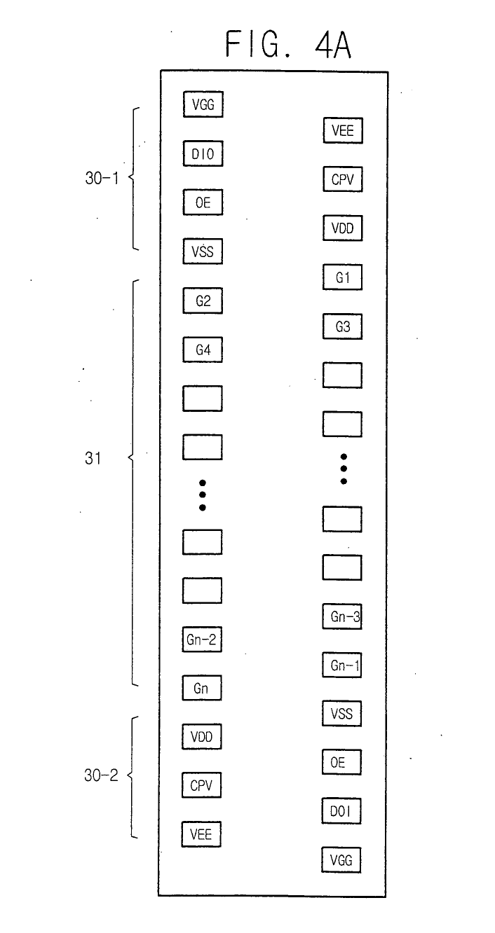

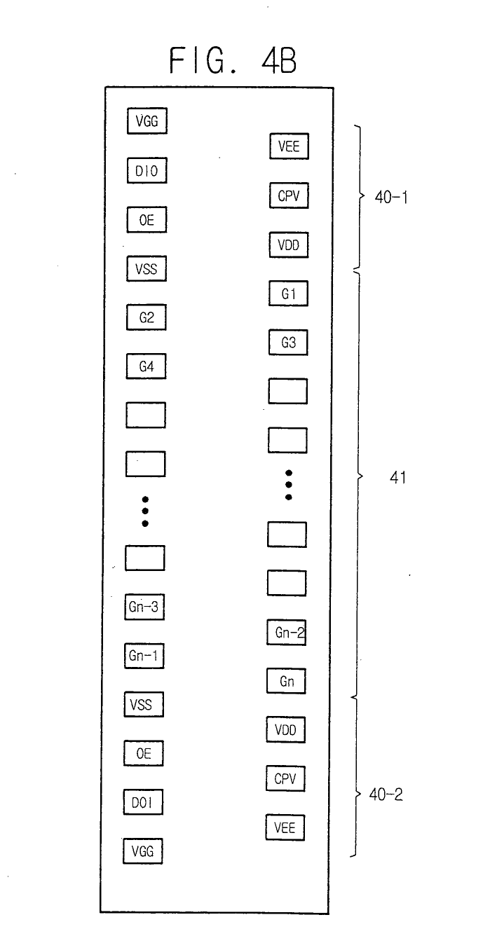

FIG. 4A illustrates an arrangement of pads when a total number of output channels for the driver IC is an even number according to one embodiment of the invention. FIG. 4B illustrates an arrangement of pads when a total number of output channels for the driver IC is an odd number according to another embodiment of the invention. Referring first to FIG. 4A, pads 300 of a signal input unit 30-1 and pads 301 of a signal output unit 30-2 are symmetrically arranged with respect to the center of the driver IC across diagonal corners of the illustrated layout. Referring to FIG. 4B, pads 400 of a signal input unit 40-1 and pads 401 of a signal output unit 40-2 are symmetrically arranged with respect to a vertical bisector line drawn across the length of the driver IC. (Of note, terms like vertical and horizontal, length and wide, etc., are used merely to designate relative locations and orientations of elements (e.g., pads) in the foregoing illustrated embodiments. The invention is, however, not limited to only the specific geometric configurations shown in the illustrated examples).

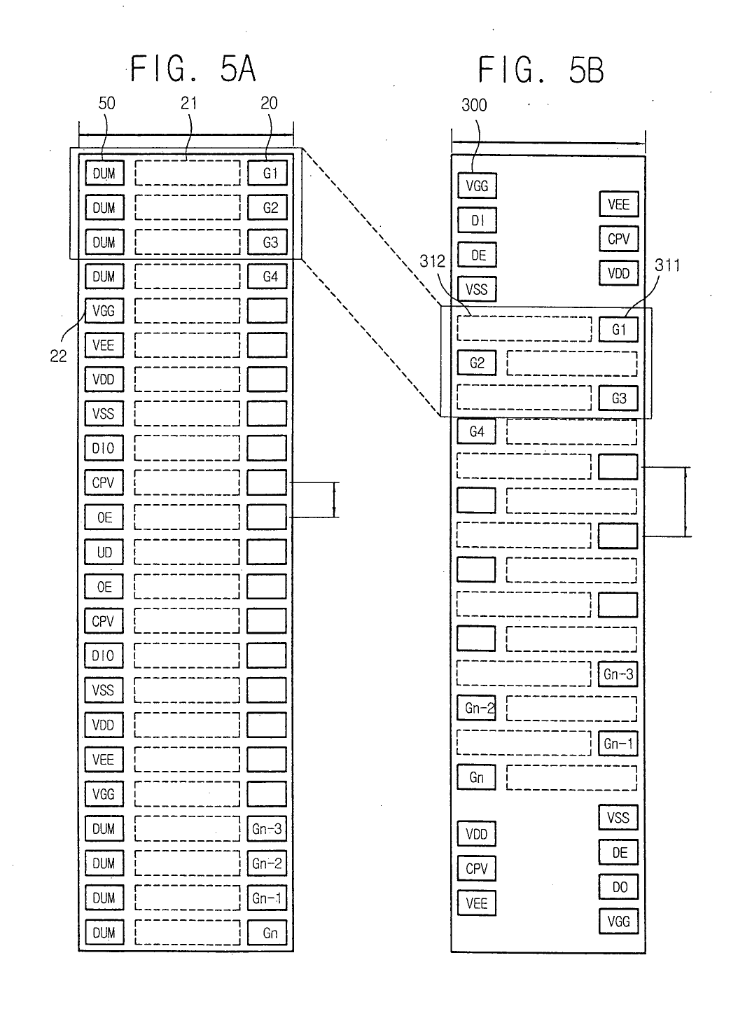

FIG. 5A illustrates an arrangement of pads for a conventional driver IC, and FIG. 5B comparatively illustrates an arrangement of pads for a driver IC according to an embodiment of the invention.

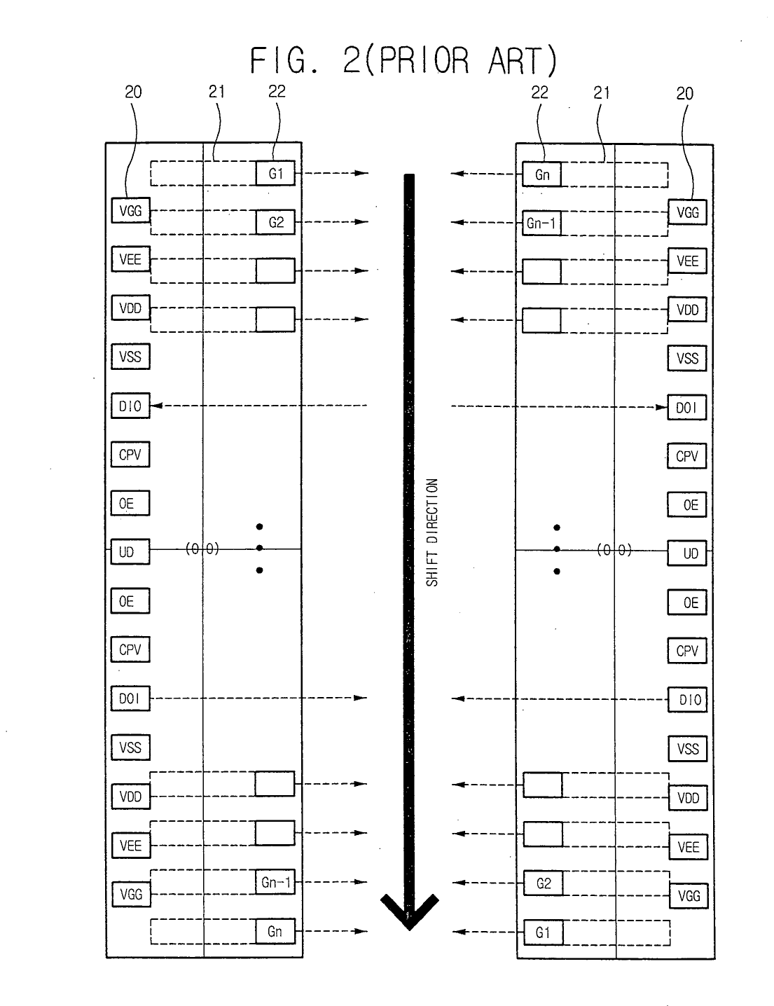

The illustrative collection of pads shown in FIGS. 5A and 5B, as similarly designated, operate in relation to the signals described above with reference to FIGS. 2 and 3. The width of the driver IC shown in FIG. 5B may be less than that of the conventional driver IC shown in FIG. 5A. Further, the interval between output channel pads 311 of the driver IC according to the present embodiment is greater than that between output channel pads 22 of the conventional driver IC, thereby further reducing signal interference between the output channel pads 311 relative to the layout of the conventional driver IC.

The conventional driver IC commonly requires dummy pads 50 in order to obtain left and right (e.g., lateral ) symmetry in embodiments where the signal I/O pads 20 are not included. In contrast, the driver IC according to the present embodiment does not require the dummy pads 50 since the output channel pads 311 are arranged to good effect in a staggered pattern.

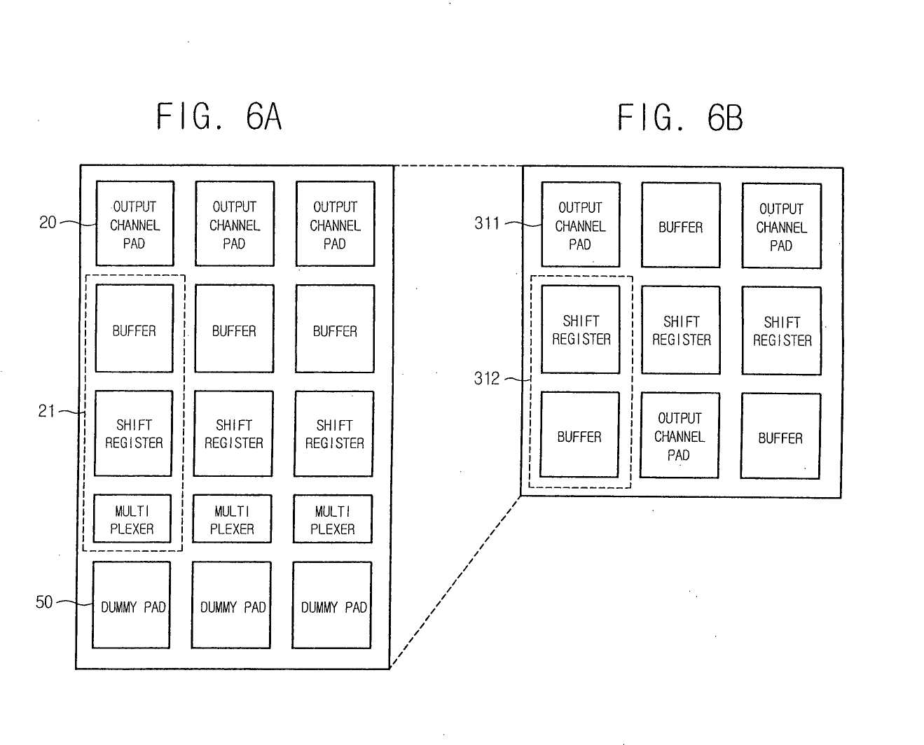

FIGS. 6A and 6B respectively illustrate in some additional detail comparative arrangements of pads for a conventional driver IC and a driver IC according to an embodiment of the invention.

As above, the illustrative collection of pads shown in FIGS. 6A and 6B, as similarly designated, operate in relation to the signals described above with reference to FIGS. 2 and 3. Referring to FIG. 6B, the driver IC according to the present embodiment does not require dummy pads 50 and multiplexers installed in the conventional driver IC of FIG. 6A, thereby reducing the size of the driver IC and eliminating unnecessary logic circuits.

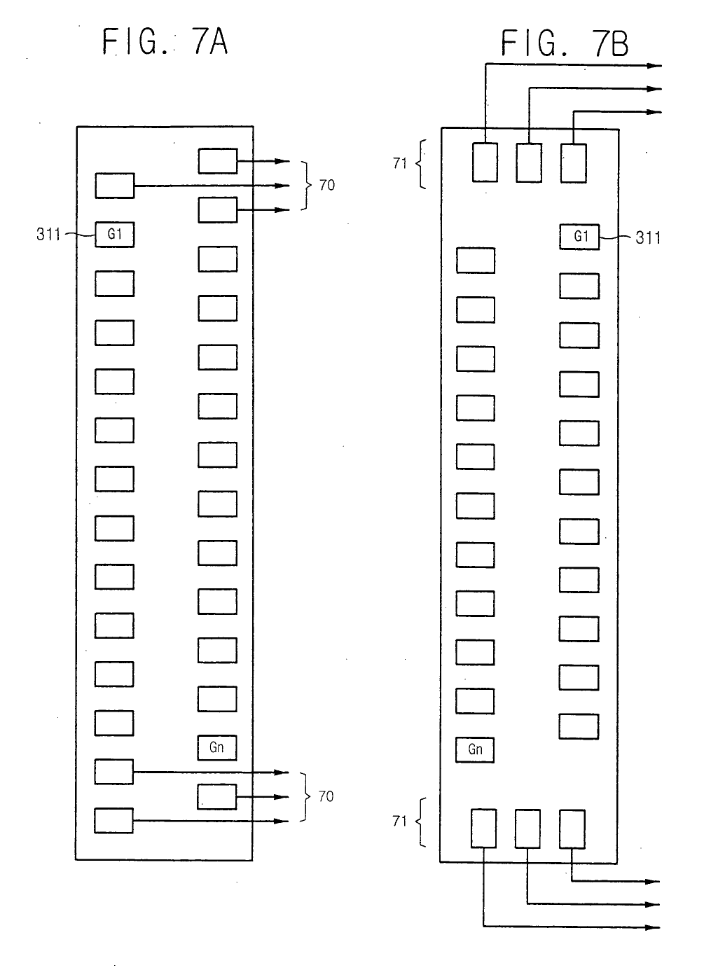

FIGS. 7A and 7B respectively illustrate arrangements of signal input/output (I/O) pads, which are different from each other, in a driver IC, according to embodiments of the invention.

Referring to FIGS. 7A and 7B, since output channel pads 311 are arranged in a staggered pattern, signal I/O pads 70 may be formed near opposite ends of the driver IC in a horizontal pattern, or signal I/O pads 71 may be formed near opposite ends of the driver IC in a vertical pattern, thereby enabling easy wiring and further reducing the overall size of the driver IC.

According to embodiments of the present invention, it is possible to fix a direction in which scan pulses are shifted by arranging output channel pads in a staggered pattern, thereby removing a need for a multiplexer that selects the direction, and input pads. Also, unlike a conventional driver IC in which output channel pads are arranged in only a single direction, the driver IC according to the present invention does not require dummy pads, thereby reducing the size of the driver IC.

Since the output channel pads are arranged in a staggered pattern, an interval between the output channel pads is increased, thus further reducing signal interference between the output channel pads. Also, since signal I/O pads are located near opposite ends of the driver IC, it is possible to wire the circuit more easily.

While the invention has been particularly shown and described with reference to exemplary embodiments thereof, it will be understood by those skilled in the art that various changes in form and details may be made therein without departing from the scope of the invention as defined by the following claims.

What is claimed is:

1. A driver integrated circuit (IC) adapted to provide driving signals to a liquid crystal display, comprising:
a signal input unit comprising first pads adapted to receive a plurality of voltages and first signals;
an output channel unit comprising a plurality of output channel pads arranged in a staggered pattern across the driver IC, and adapted to receive and process the first signals, and output results as the driving signals via the plurality of output channel pads; and
a signal output unit comprising second pads adapted to receive the plurality of voltages, and output second signals in accordance with the driving signals.

2. The driver IC of claim 1, wherein the signal input unit and the signal output unit are respectively located near opposite ends of the driver IC and bracket the output channel unit.

3. The driver IC of claim 1, wherein the first and second pads are respectively arranged in parallel.

4. The driver IC of claim 1, wherein the first and second pads are respectively arranged in a staggered pattern.

5. The driver IC of claim 4, wherein when a total number of the output channel pads is an even number, and wherein the first pads and the second pads are symmetrically arranged along opposite diagonals drawn across the length of the driver IC.

6. The driver IC of claim 4, wherein a total number of the output channel pads is an odd number, and wherein the first pads and the second pads are symmetrically arranged across a vertical bisector line drawn across the length of the driver IC.

7. The driver IC of claim 1, wherein each of the driving signals is a pulse signal having a single pulse, and wherein the output from the plurality of output channel pads in response to the single pulse shifted along the plurality of output channel pads is fixed in a single direction.

8. A method of arranging pads in a driver integrated circuit adapted to provide driving signals to a liquid crystal display, the method comprising:
arranging a plurality of first pads on one end of a driver integrated circuit (IC);
arranging a plurality of output channel pads adapted to output the driving signals in a staggered pattern across the driver IC; and
arranging a plurality of second pads on an opposite end of the driver IC, such that the plurality of output channel pads is bracketed between the plurality of first pads and the plurality of second pads.

9. The method of claim 8, wherein the plurality of first pads are adapted to receive a plurality of voltages and first signals.

10. The method of claim 8, wherein the plurality of second pads are adapted to receive the plurality of voltages, and output second signals in accordance with the driving signals.

11. The method of claim 8, wherein the plurality of first pads and the plurality of second pads are respectively arranged in parallel.

12. The method of claim 8, wherein the plurality of first pads and the plurality of second pads are respectively arranged in a staggered pattern.

13. The method of claim 12, wherein when a total number of the output channel pads is an even number, and wherein the plurality of first pads and the plurality of second pads are symmetrically arranged along opposite diagonals drawn across the length of the driver IC.

14. The method of claim 12, wherein when a total number of the output channel pads is an odd number, and wherein the plurality of first pads and the plurality of second pads are symmetrically arranged across a vertical bisector line drawn across the length of the driver IC.

15. A dual-bank driver integrated circuit (IC) adapted for use on opposite sides of a liquid crystal display (LCD) panel and further adapted to provide first driving signals and second driving signals in a directionally similar sequence, to the LCD panel, the dual-bank driver IC comprising:
a plurality of first driver integrated circuits located on a side of the LCD panel and adapted to provide the first driving signals to the LCD panel through first output channel pads arranged in a pattern on each respective first driver integrated circuit; and
a plurality of second driver integrated circuits located on an opposite side of the LCD panel and adapted to provide the second driving signals through second output channel pads arranged identically with the first output pads.

16. The dual-bank driver IC of claim 15, wherein the first and second output channel pads are respectively arranged in a staggered pattern across respective first and second driver integrated circuits.

17. The dual-bank driver IC of claim 16, wherein each of the first and second driver integrated circuits comprises first pads and second pads respectively located near opposite ends of the respective first and second driver integrated circuits so as to bracket respective first and second output channel pads.

18. The dual-bank driver IC of claim 17, wherein the first and second pads are respectively arranged in parallel.

19. The dual-bank driver IC of claim 17, wherein the first and second pads are respectively arranged in a staggered pattern.

20. The dual-bank driver IC of claim 19, wherein when a total number of each of the first and second output channel pads is even number, and wherein the first pads and the second pads are respectively symmetrically arranged along opposite diagonals drawn respectively across the length of the first and second driver integrated circuits.

21. The dual-bank driver IC of claim 19, wherein when a total number of each of the first and second output channel pads is an odd number, and wherein the first pads and the second pads are symmetrical arranged across a vertical bisector line drawn respectively across the length of the first and second driver integrated circuits.
